(19) United States
(12) Patent Application Publication
(10) Pub. No.: US 2026/0129977 A1
(43) Pub. Date: May 7, 2026

(54) CONTROLLABLE TRIGGERED ELECTROSTATIC DISCHARGE DEVICE WITH NANOSHEET GATES

(71) Applicant: INTERNATIONAL BUSINESS MACHINES CORPORATION, ARMONK, NY (US)

(72) Inventors: Anindya Nath, Watervliet, NY (US); Robert Gauthier, Williston, VT (US); Masoud Zabihi, Schenectady, NY (US); Anthony I-Chih Chou, Guilderland, NY (US); Ruilong Xie, Niskayuna, NY (US)

(21) Appl. No.: 18/935,383

(22) Filed: Nov. 1, 2024

(51) Int. Cl. H01L 27/02

(52) U.S. Cl. CPC H10D 89/711

(57) ABSTRACT

A semiconductor device includes a base including a first doped region, a second doped region and a plurality of nanosheet gates, a collector including a third doped region, and an emitter including a fourth doped region. The plurality of nanosheet gates is configured to control a resistance of the base.

### BACKGROUND

### Technical Field

The present disclosure generally relates to semiconductors, and more particularly, to controllable triggered nanosheet gate electrostatic discharge structure, and methods of creation thereof.

### Description of Related Art

The continuous miniaturization of transistors and their increasing density on chips are hallmark innovations in the semiconductor industry, closely following Moore's Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a base having a base including a first doped region, a second doped region and a plurality of nanosheet gates, a collector including a third doped region, and an emitter including a fourth doped region. The plurality of nanosheet gates is configured to control a resistance of the base.

In an embodiment, the semiconductor device is a lateral N-type/P-type/N-type (LNPN) device, or a lateral P-type/N-type/P-type (LPNP) device.

In an embodiment, the semiconductor device includes a first well region below the collector and the emitter, and a second well region below the first well region and the base.

In an embodiment, each of the base, the emitter, and the collector further includes a spacer layer over sidewalls of a set of gate regions.

In an embodiment, each of the base, the emitter, and the collector includes a frontside contact.

In an embodiment, the plurality of nanosheet gates includes alternative layers extended horizontally between the corresponding doped region and a gate region.

In an embodiment, the alternative layers include silicon.

According to an embodiment, a method of fabricating a semiconductor device includes forming a base including a first doped region, a second doped region and a plurality of nanosheet gates, forming a collector including a third doped region, forming an emitter including a fourth doped region, and controlling a resistance of the base via the nanosheet gates.

In an embodiment, the semiconductor device is a lateral N-type/P-type/N-type (LNPN) device, or a lateral P-type/N-type/P-type (LPNP) device.

In an embodiment, the method includes forming a first well region below the collector and the emitter, and forming a second well region below the first well region and the base.

In an embodiment, forming each of the base, the emitter, and the collector includes forming a spacer layer over sidewalls of a gate region.

In an embodiment, forming the plurality of nanosheet gates includes extending the plurality of nanosheet gates horizontally between a corresponding doped region and a gate region.

In an embodiment, the plurality of nanosheet gates includes silicon.

According to an embodiment, a semiconductor deice includes a base including a first doped region, a second doped region, a plurality of nanosheet gates, a collector including a third doped region, and an emitter including a fourth doped region. The plurality of nanosheet gates and an electrical connection between the base and the emitter are configured to control a resistance of the base.

In an embodiment, the semiconductor device is a lateral N-type/P-type/N-type (LNPN) device, or a lateral P-type/N-type/P-type (LPNP) device.

In an embodiment, the semiconductor device includes a first well region below the collector and the emitter, and a second well region below the first well region and the base.

In an embodiment, each of the base, the emitter, and the collector includes a spacer layer over sidewalls of a set of gate regions.

In an embodiment, each of the base, the emitter, and the collector includes the plurality of nanosheet gates includes alternative layers extended horizontally between the corresponding doped region and a gate region.

In an embodiment, the alternative layers include silicon.

In an embodiment, each of the base, the emitter, and the collector includes a frontside contact.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates exemplary circuitry of a planar complementary metal oxide semiconductor device.

FIG. 1B illustrates schematically an electrostatic discharge device operation during the normal circuit operation voltage range, electrostatic discharge operating window during an electrostatic discharge event, and the failure region.

FIG. 2A illustrates a conventional electrostatic discharge device.

FIG. 2B illustrates a conventional electrostatic discharge device circuitry.

FIG. 2C illustrates an I-V diagram of a conventional electrostatic discharge device.

FIGS. 3A-3B illustrate an electrostatic discharge device, in accordance with an embodiment.

FIG. 4A illustrates an I-V diagram for an electrostatic discharge device, in accordance with an embodiment.

FIG. 4B illustrates an electrostatic discharge device circuitry associated with the semiconductor device shown in FIG. 3A.

FIG. 4C illustrates an electrostatic discharge device circuitry associated with the semiconductor device shown in FIG. 3B.

FIG. 5 illustrates a block diagram of a method for forming the semiconductor device, in accordance with an embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

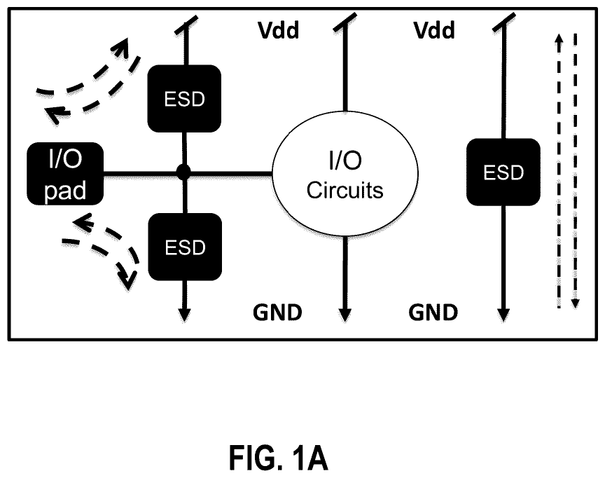

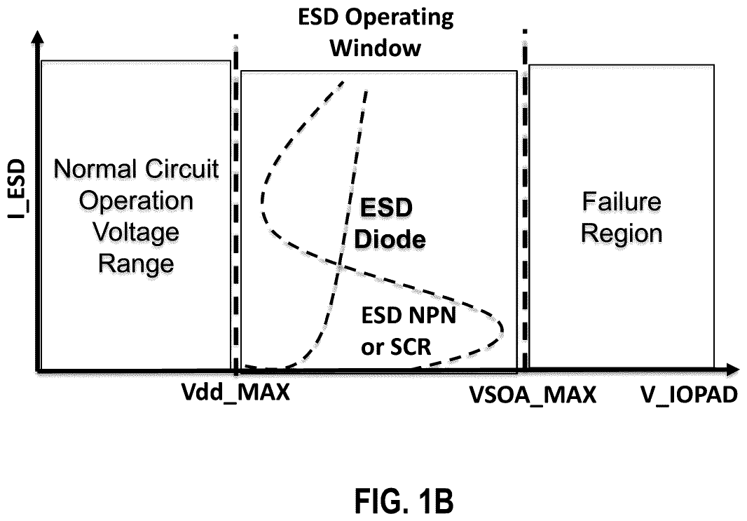

FIG. 1A illustrates exemplary circuitry of a planar complementary metal oxide semiconductor device. An Electrostatic Discharge (ESD) protection device can shield sensitive components from sudden voltage spikes caused by static electricity. The protection mechanism utilizes key components such as the power supply voltage (VDD), ground (GND), input/output (I/O) pads, and I/O devices within its circuitry to prevent damage during an ESD event. Under normal operating conditions, the ESD protection device remains inactive, allowing signals to pass freely between the I/O pads and the internal circuitry without interference. The I/O devices function as intended, transmitting data and signals seamlessly.

When an ESD event occurs—such as a high-voltage spike from static discharge contacting an I/O pad—the ESD protection device detects the sudden voltage increase. It rapidly activates to respond to this abnormal voltage level. The device provides a low-resistance path for the excess charge to flow safely to ground (GND), thereby preventing the high voltage from reaching and damaging the internal I/O devices and other circuitry. In some designs, the ESD device may also divert current to the power supply voltage (VDD) rail, helping to balance voltage levels and further protect the circuit.

The ESD protection device clamps the voltage at the I/O pad to a safe level using components like diodes, thyristors, or specially designed transistors. The clamping action ensures that the voltage across sensitive components does not exceed their tolerance limits. The excess energy from the ESD event is dissipated within the ESD protection circuitry, which is engineered to handle the thermal stress without sustaining damage.

After the ESD event subsides, the protection device returns to its high-resistance, inactive state. Normal operation of the I/O pads and devices resumes without any degradation in performance. By integrating the ESD protection circuitry with the VDD, GND, I/O pads, and I/O devices, engineers ensure that semiconductor devices can withstand electrostatic discharges encountered during handling, assembly, or everyday use.

This integrated approach is crucial for the durability and functionality of modern electronic systems, which prevents physical damage to semiconductor components, enhances overall reliability, and maintains signal integrity by minimizing interference during normal operation. FIG. 1B illustrate schematically how an ESD device operates during the normal circuit operation voltage range, ESD operating window during an ESD event, and the failure region.

For low-power applications, particularly in advanced semiconductor technologies such as the 2-nanometer (nm) technology node, there is a pressing need for electrostatic discharge (ESD) protection devices that have trigger voltages lower than the typical reverse-bias breakdown voltage of conventional devices. As the industry progresses towards smaller geometries, the supply voltages decrease, and the voltage margins become tighter. This reduction means that traditional ESD protection mechanisms, which rely on higher trigger voltages, may not activate in time to protect sensitive components without interfering with normal circuit operation.

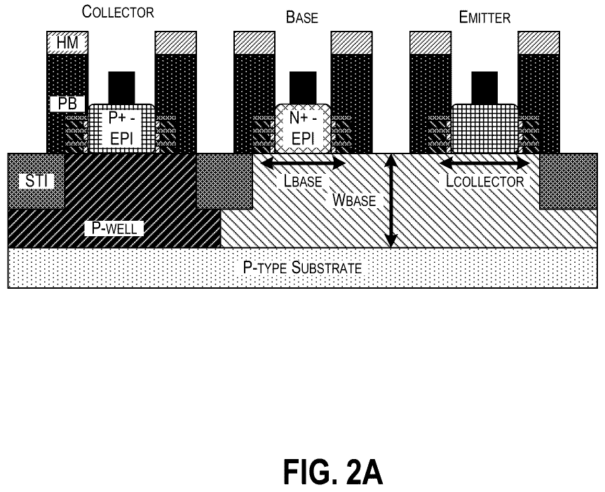

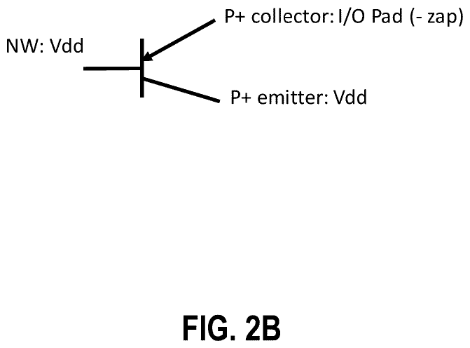

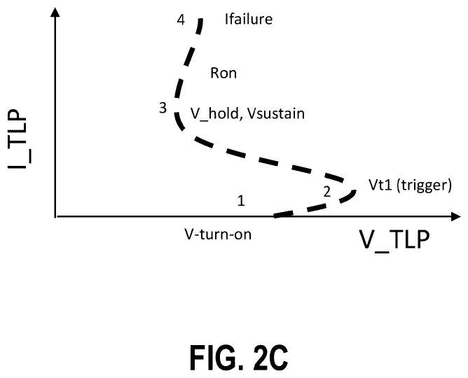

FIG. 2A illustrates a conventional electrostatic discharge device. FIG. 2B illustrates a conventional electrostatic discharge device circuitry. FIG. 2C illustrates an I-V diagram of a conventional electrostatic discharge device. The ESD protection device shown in FIG. 2A operates by leveraging the behavior of a parasitic bipolar junction transistor (BJT) inherent in semiconductor structures. Such a device protects sensitive electronic components by providing a controlled path for excess charge during an ESD event. The operation of the device can be understood through four regions: leakage (pre-turn on), trigger/turn-on, holding/sustaining, and failure. In the leakage or pre-turn-on region (Region 1), the device is under normal operating conditions with no significant ESD stress. The voltage across the device is low, and only minimal leakage currents flow between the collector and emitter. The parasitic BJT remains inactive, allowing the normal functioning of the circuit without any interference from the ESD protection device.

As an ESD event occurs, the voltage at the collector increases rapidly. When this voltage reaches the trigger voltage (Vt1), the device enters the trigger or turn-on region (Region 2). At this point, the voltage is sufficient to forward-bias the base-emitter junction and reverse-bias the base-collector junction of the parasitic BJT. This condition causes a significant increase in current flow from the collector to the emitter. The device effectively becomes conductive, providing a low-resistance path characterized by the on-resistance (Ron). This path diverts the ESD current away from sensitive components, preventing damage.

Once the device is conducting, it transitions into the holding or sustaining region (Region 3). In this phase, the voltage across the device decreases due to the low Ron, but the current remains high as it continues to conduct the ESD current. The device maintains this conductive state as long as the current exceeds the holding current threshold, ensuring that the excess energy from the ESD event is safely shunted away from critical circuitry.

If the ESD event introduces a voltage or current that exceeds the device's capacity, the device enters the failure region (Region 4). This occurs when the voltage surpasses the failure voltage (Vfail or Vt2) or the current exceeds the failure current (Ifail or It2). In this region, the device can no longer handle the stress, leading to breakdown and potential damage to both the ESD protection device and the circuitry it was designed to protect. The device's ability to handle the ESD event is also influenced by the load capacitance (Cload), which affects its response time and ability to absorb transient energies. In the specific configuration depicted in FIG. 2C, where VDD is an N-well, the P+ collector is connected to the I/O pad (which is subject to the ESD event), and the P+ emitter is connected to another VDD, the device operates as follows: during an ESD event, the I/O pad connected to the P+ collector experiences a sudden voltage spike. The N-well, acting as the base of the parasitic PNP transistor, is connected to VDD. The P+ emitter, also connected to VDD, serves as the return path. As the voltage at the collector rises sharply due to the ESD pulse, the base-collector junction becomes reverse-biased, while the base-emitter junction remains forward-biased because both the base and emitter are at VDD potential.

This biasing condition activates the parasitic PNP transistor. The ESD current begins to flow from the collector (I/O pad) through the base (N-well) to the emitter (VDD), effectively creating a low-resistance path that diverts the ESD current away from the internal circuitry. The activation occurs precisely at the trigger voltage (Vt1), which is designed to be lower than the typical reverse-bias breakdown voltage of standard devices. This ensures that the ESD protection device responds quickly before the voltage reaches levels that could harm the sensitive components.

The effectiveness of the device during the holding/sustaining region depends on the on-resistance (Ron). A lower Ron allows the device to conduct the ESD current more efficiently, resulting in a lower voltage drop across the device during the ESD event. This helps keep the voltage within safe limits for the protected circuitry. The device continues to conduct until the ESD event subsides and the current falls below the holding current threshold, after which the device returns to its high-resistance, inactive state. If the ESD stress exceeds the device's designed capacity—surpassing Vfail (Vt2) or Ifail (It2)—the device may enter the failure region. In this scenario, the parasitic BJT cannot handle the excessive energy, leading to thermal runaway or junction breakdown. This failure can result in permanent damage to the ESD protection device and potentially to the connected circuitry.

The load capacitance (Cload) plays a crucial role in the device's performance during an ESD event. A higher Cload can slow down the voltage rise at the collector, giving the ESD protection device more time to activate. However, it can also slow down the response time in high-speed applications, affecting signal integrity during normal operation. Therefore, optimizing Cload is essential to balance ESD protection effectiveness and circuit performance.

The present disclosure discloses an integrated nanosheet-bulk hybrid device implemented to achieve the required low trigger voltage for effective ESD protection. The nanosheet architecture allows for precise control over the channel dimensions and electrical characteristics at the nanoscale, enabling the engineering of devices with specific threshold voltages. By integrating nanosheet transistors with bulk semiconductor properties, the hybrid device leverages the advantages of both technologies.

The nanosheet component provides a high degree of electrostatic control due to its thin and wide channel structure. This geometry enhances the gate's ability to modulate the channel, allowing the device to respond rapidly to voltage changes. When an ESD event occurs, the enhanced electrostatic control facilitates a quicker turn-on of the protection device at a lower trigger voltage. Such a rapid activation facilitates diverting the high ESD currents away from vulnerable circuit elements before damage can occur.

Meanwhile, the bulk component of the hybrid device contributes to improved current-handling capabilities. Bulk materials can sustain higher current densities without degrading, which is important during an ESD event where substantial currents need to be safely conducted to ground. The combination of nanosheet electrostatics with bulk robustness ensures that the device not only activates promptly but also withstands the stress of the discharge without failure. By carefully designing the doping profiles, material compositions, and geometric configurations of the nanosheet-bulk hybrid device, the discloses semiconductor device provides a fine-tuned trigger voltage to be below the reverse-bias breakdown voltage of traditional devices yet above the maximum operating voltage of the circuit. The precision ensures that during normal operation, the ESD protection device remains non-intrusive, avoiding any impact on the circuit's performance. However, when an ESD event introduces a sudden voltage spike, the device activates swiftly to provide a low-resistance path for the excess charge, effectively safeguarding the low-power components.

The disclosed semiconductor device can be utilized in 2 nm technology nodes, where devices are more susceptible to damage due to their reduced size and thinner gate oxides. The decreased dimensions amplify the electric fields within the device, making them more vulnerable to breakdown during ESD events. The nanosheet-bulk hybrid ESD protection device addresses these challenges by offering a scalable solution that maintains effectiveness even as device dimensions continue to shrink.

As such, the implementation of an integrated nanosheet-bulk hybrid device for ESD protection represents a significant advancement in semiconductor technology. It enables the creation of ESD protection devices with low trigger voltages suitable for low-power applications, ensuring the reliability and longevity of electronic components in cutting-edge technology nodes such as 2 nm. This approach balances the need for rapid response and high current-handling capacity within a compact design, meeting the stringent requirements of modern integrated circuits.

Accordingly, the teachings herein provide methods and systems with controllable triggered nanosheet gate electrostatic discharge structure. The techniques described herein may be implemented in a number of ways. Example implementations are provided below with reference to the following figures.

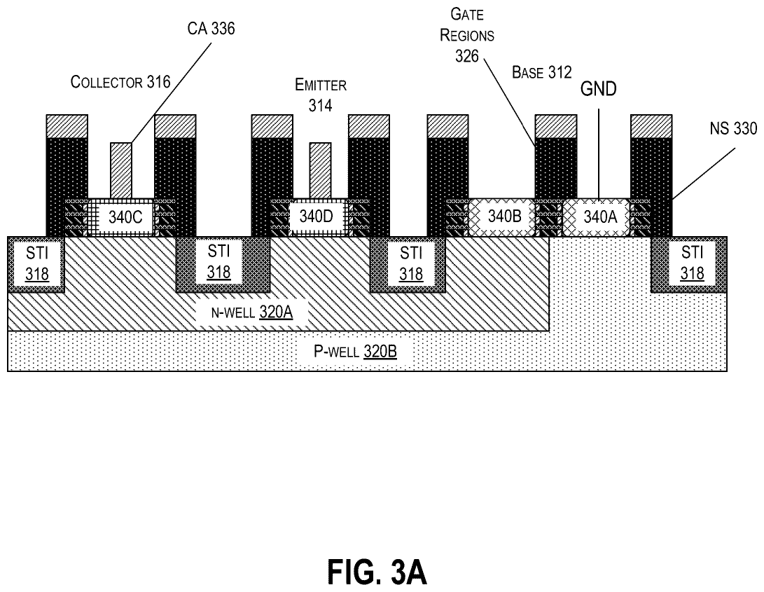

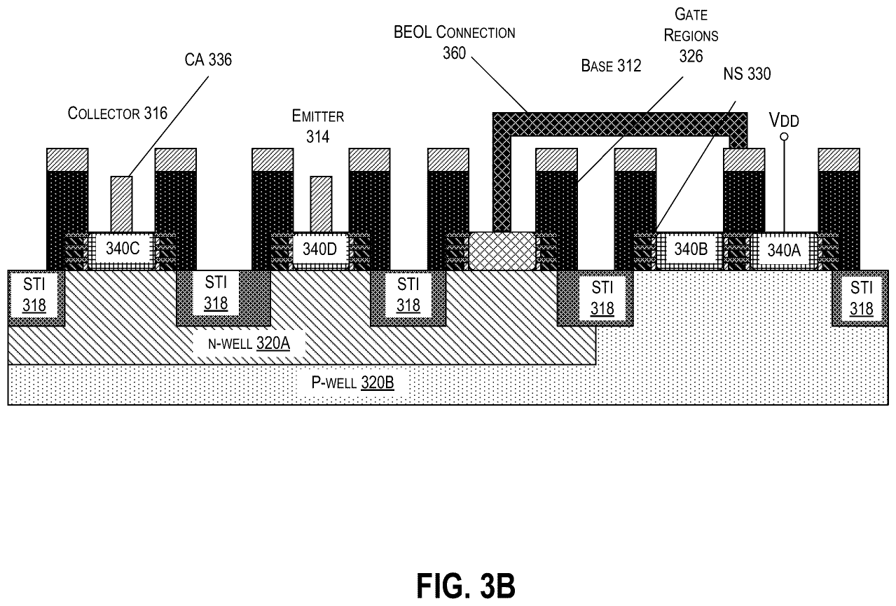

Example Semiconductor Device Controllable Triggered Nanosheet Gate ESD Structure Reference now is made to FIGS. 3A-3B, which are simplified cross-section views of a semiconductor device, consistent with an illustrative embodiment. The semiconductor device can include a base 312 that includes a first doped region, N-doped 340A, a second doped region, N-doped 340B, and a plurality of nanosheet gates, NS 330. The NS 330 are configured to control the resistance of the base 312, allowing modulation of electrical properties essential for the device's operation. The collector 316 includes a third doped region, P-doped 340C and the emitter 314 includes a fourth doped region, P-doped 340D. The arrangement of the doped regions facilitates efficient charge carrier movement, enhancing the overall performance of the device. The semiconductor device can include shallow trench isolation, STI 318, an interlayer dielectric, an N-well 320A, a P-well 320B, gate regions 326, and frontside contacts, CA 336.

The semiconductor device can incorporate a junction that is partially isolated from the bulk substrate which can enhance the device's performance and reliability. This partial isolation is achieved through techniques such as shallow trench isolation or the introduction of doped regions that create a controlled level of electrical separation between the junction and the substrate. The partial isolation allows for some interaction with the substrate while providing enough resistance to influence current flow and electric field distribution within the device. The junction with partial isolation is ingeniously utilized as part of the lateral bipolar transistor's emitter and/or collector regions. In this configuration, the junction serves to introduce local ballasting or series resistance. Local ballasting is a feature that helps in distributing current evenly across the transistor, preventing current crowding and the formation of hot spots that can lead to thermal runaway or device failure. The series resistance provided by the partially isolated junction ensures that the current does not concentrate in any single area, thereby enhancing the thermal stability and reliability of the lateral bipolar transistor.

Furthermore, the same junction is employed as part of the drain and/or source regions of a field-effect transistor (FET). The partial isolation can contribute local ballasting or series resistance, which manages the electric fields within the FET. By introducing a controlled resistance in the drain and source regions, the semiconductor device mitigates issues such as hot carrier injection, where high-energy carriers can degrade the gate oxide or the semiconductor material. The series resistance also helps in controlling the voltage drops across the FET, reducing the electric field stress on critical regions and improving the overall robustness of the device.

The use of the partially isolated junction in both the lateral bipolar transistor and the FET signifies a multifunctional approach to device design. By serving as a component in both types of transistors, the junction enables the integration of different transistor technologies within a single semiconductor substrate. This integration can lead to more compact device architectures, reduced parasitic elements, and enhanced performance characteristics.

The partial isolation of the junction provides sufficient electrical separation to introduce the desired series resistance while maintaining enough connectivity to allow the necessary current flow for device operation.

Each of the N-well 320A and the P-well 320B can be created by doping with a type P dopant, which introduces an excess of positive charge carriers (holes), or with a type N dopant, which introduces an excess of negative charge carriers (electrons). An N-well region and a P-well region can form the p-n junction of the semiconductor device. The p-n junction can control the flow of electrical current within the semiconductor device. The p-n junction can be created by doping two adjacent regions, one with a type P dopant, which introduces an excess of positive charge carriers (holes), and the other with a type N dopant, which introduces an excess of negative charge carriers (electrons). At the interface between the P and N regions, a depletion region forms due to the diffusion of electrons from the N region into the P region and the diffusion of holes in the opposite direction. Such a diffusion process continues until the electric field created by the accumulation of charge at the junction balances the diffusion forces, resulting in a zone depleted of free charge carriers. In its natural state, the p-n junction allows current to flow more easily in one direction than in the opposite.

When forward biased, i.e., positive voltage applied to the P side relative to the N side, the depletion region narrows, lowering the barrier for charge carriers to move across the junction, and allowing current to flow through the device. Conversely, when reverse-biased, i.e., negative voltage applied to the P side, the depletion region widens, increasing the barrier for charge movement, and significantly reducing the flow of current.

The STI 318 can electrically isolate different components by filling the trenches with an insulating material, such as silicon dioxide. The STI 318 can prevent electrical interference and crosstalk between adjacent devices, ensuring that each component operates independently without affecting its neighbors.

Beneath the collector 316 and emitter 314, the first well region, N-well 320A, is located. Below this N-well 320A and the base 312 lies a second well region, P-well 320B. The well regions serve to isolate the active components of the device from the substrate, reducing parasitic capacitance and preventing unwanted leakage currents. The well regions also influence the electrical characteristics by modifying the doping profiles and the depth of the junctions, which is crucial for tailoring the device's behavior to specific requirements.

Each of the base 312, emitter 314, and collector 316 includes a spacer layer over the sidewalls of the gate regions 326. The spacer layer can be composed of dielectric materials, helping define the gate length and minimize short-channel effects. The spacer layer can reduce parasitic capacitance between the gate and the source/drain regions. By managing the electric fields within the device, the spacer layer can contribute significantly to the overall efficiency and reliability.

Additionally, the base 312, emitter 314, and collector 316 each include a frontside contact, CA 336. The CA 336 provide electrical connections to external circuits, ensuring that the device can be integrated seamlessly into larger electronic systems In various embodiments, the gate regions 326 serve as control elements that regulate the flow of current through the semiconductor device. The gate regions 326 can be composed of a conductive material. The gate regions 326 can control the flow of electric current between the source and drain regions. In addition to acting as a switch, modulating the gate voltage can enable the gate regions 326 to control the current flowing through the channel region, resulting in amplified output signals.

In an embodiment, the gate regions 326 can enable the implementation of Boolean active operations, such as AND, OR, and NOT, by controlling the flow of current based on the input voltages. In some embodiments, the gate regions 326, along with other active device components, can facilitate the miniaturization and integration of electronic circuits. The ability to control the channel region's conductivity through the gate voltage allows for compact and highly efficient circuit designs.

The NS 330 includes alternative layers extended horizontally between the corresponding doped region and a gate region. The NS 330 can be thin sheets of semiconductor material, e.g., silicon, stacked vertically and separated by insulating layers. Extending horizontally, the NS 330 increase the effective channel width without enlarging the device's footprint, enabling higher drive currents and improved performance. The nanosheet structure provides gate control over the channel, enhancing switching speeds and reducing leakage currents. The alternative layers include silicon, chosen for its semiconductor properties, such as high carrier mobility and thermal stability.

The combination of advanced doping techniques, isolation methods, and nanosheet gate technology, allows the semiconductor device to deliver highly controlled, efficient current flow. Such a combination is particularly well-suited for applications in power amplification, signal switching, and integrated circuits where performance, scaling, and reliability are essential, while it will be understood that the teachings herein can be used in many other applications as well.

The base 312 is formed from a second doped region accompanied by a second contact, CA 336, located on top, similarly facilitating electrical connectivity. The collector 316 includes a third doped region with a third contact, CA 336, positioned above it. The emitter 314 is constructed with a fourth doped region capped by a fourth contact, CA 336, that interfaces with the emitter's electrical output.

The collector 316 and the base 312 can be electrically isolated from each other through the use of the STI 318 or floating gates. The floating gates, which are electrically isolated and surrounded by a dielectric layer, can be used for specific applications requiring capacitive coupling and more advanced control of electrical properties.

The semiconductor device can function as a lateral N-type/P-type/N-type (LNPN) device or a lateral P-type/N-type/P-type (LPNP) device. In the LNPN configuration, the base is P-type and is situated between N-type collector and emitter regions. This arrangement enables electron flow across the base when appropriate voltage biases are applied. In the LPNP configuration, the base is N-type and is sandwiched between P-type collector and emitter regions, allowing hole flow through the base. The ability to configure the device as either LNPN or LPNP adds versatility, making it suitable for various applications requiring different types of charge carriers.

In some embodiments, the emitter 314, collector 316, base 312, and guard ring can be formed using epitaxial (epi) junctions, which are grown by employing adjacent “cut” nanosheets and bulk silicon as epitaxial seeds. The use of epitaxial growth allows for the formation of high-quality crystalline layers that are essential for the optimal performance of semiconductor devices. The “cut” nanosheets refer to nanoscale sheets of semiconductor material that have been precisely patterned and etched to define specific regions within the device. By using such nanosheets as templates, the epitaxial layers can be grown with exacting control over their thickness, composition, and doping profiles. The bulk silicon acts as a seed layer for the epitaxial growth, ensuring that the newly formed layers have the same crystalline orientation and properties as the underlying substrate.

The raised emitter, collector, base, and guard ring can be separated within the bulk silicon by STI structures or floating gates. STI can electrically isolate individual components within an integrated circuit by creating shallow trenches in the silicon substrate and filling them with an insulating material, such as silicon dioxide. Such an isolation can facilitate preventing electrical crosstalk and leakage currents between adjacent regions, which can degrade the performance of the device.

The guard ring encircles the active regions of the device, providing an additional layer of protection and isolation. The guard ring helps in confining the electric fields within the device during high-voltage conditions, such as an ESD event. By containing these fields, the guard ring prevents them from affecting neighboring components, thereby enhancing the robustness and reliability of the semiconductor device. In some embodiments, the base resistance of the PNP (or NPN) transistor is modulated by an integrated nanosheet n-type field-effect transistor (nFET). The nanosheet nFET is built into the device using the same nanosheet technology employed for the emitter 314, collector 316, and base 312. By integrating the nFET directly into the base region, it becomes possible to dynamically control the resistance of the base.

The modulation of the base resistance can be achieved by varying the gate voltage of the nanosheet nFET. When a voltage is applied to the gate of the nFET, it alters the conductivity of the channel within the nanosheet, thereby changing the amount of current that can flow through the base region of the PNP (or NPN) transistor. Such a control over the base current allows for fine-tuning of the transistor's switching characteristics and responsiveness.

During normal operation, the ability to adjust the base resistance improves the device's performance by optimizing parameters such as gain and switching speed. In case of the ESD protection device, this feature enables the device to respond more effectively to sudden voltage spikes. By lowering the base resistance during an ESD event, the device can quickly turn on and provide a low-resistance path for the discharge current, thereby protecting sensitive components from damage. The use of nanosheets offers electrostatic control due to their thin and planar geometry, which reduces short-channel effects and allows for scaling to very small dimensions.

Reference is now made to FIG. 3B, which illustrates a semiconductor device including a base 312, an emitter 314, a collector 316, shallow trench isolation, STI 318, an interlayer dielectric, an N-well 320A, a P-well 320B, gate regions 326, a plurality of nanosheet gates, NS 330, and frontside contacts, CA 336.

The semiconductor structure shown in FIG. 3B features a lateral PNP (or NPN) transistor where the base resistance is modulated by an isolated nanosheet p-type field-effect transistor (pFET) and BEOL connection 360. Such an integration allows for control over the base resistance, enhancing the transistor's performance and making it particularly effective for applications such as electrostatic discharge (ESD) protection. In this structure, the nanosheet pFET is embedded within the base 312 of the lateral PNP (or NPN) transistor. The nanosheet pFET is constructed using ultra-thin layers of semiconductor material—such as silicon—formed into nanosheets that extend horizontally. The NS 330 provide a large surface area in a compact form, enabling electrostatic control over the channel where current flows. The pFET is isolated from other device regions using techniques such as STI, ensuring that its operation does not interfere with adjacent components.

The gate circuitry, e.g., the BEOL connection 360, associated with the nanosheet pFET can modulate the conductivity of the pFET channel, thereby controlling the base resistance of the PNP (or NPN) transistor. The gate electrode of the pFET is connected to the gate circuitry, which supplies the necessary gate voltage to influence the channel's charge carrier density. By adjusting the gate voltage, the electric field across the nanosheet channel is altered, which in turn changes the channel's resistance. When a voltage is applied to the gate electrode, it affects the holes—the primary charge carriers in a p-type channel—in the nanosheet. A positive gate voltage depletes holes from the channel, increasing its resistance, while a negative gate voltage enriches the channel with more holes, decreasing its resistance. This modulation directly impacts the base resistance of the PNP transistor because the nanosheet pFET is integrated into the base region. By fine-tuning the gate voltage through the gate circuitry, the base resistance can be dynamically adjusted to optimize the transistor's performance under different operating conditions.

The gate circuitry can include conductive pathways and control elements that deliver the desired gate voltage to the nanosheet pFET. The gate circuitry can involve voltage sources, biasing resistors, and optionally control signals from other parts of the integrated circuit. The materials used for the gate electrode can include metals or heavily doped polysilicon, chosen for their conductivity and compatibility with semiconductor processing.

Integrating the nanosheet pFET and its gate circuitry within the transistor's base region allows for real-time adjustment of the base resistance, which is important for controlling the transistor's switching speed, gain, and response to transient events such as ESD occurrences. During an ESD event, the ability to lower the base resistance rapidly enables the transistor to turn on more quickly, providing an effective path for the excess charge to be safely discharged. This responsiveness enhances the protection of sensitive components connected to the transistor.

Moreover, the nanosheet structure provides electrostatic control due to its geometry. The thinness of the nanosheets ensures that the gate electric field can effectively modulate the entire channel, reducing short-channel effects that are common in scaled-down devices, which can facilitate maintaining device performance as semiconductor technologies advance toward smaller nodes, such as 2-nanometer technology.

The semiconductor device is depicted as being on silicon as the substrate, while it will be understood that other types as the substrate may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

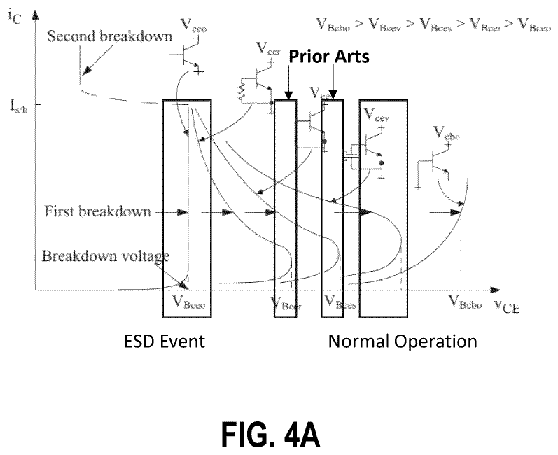

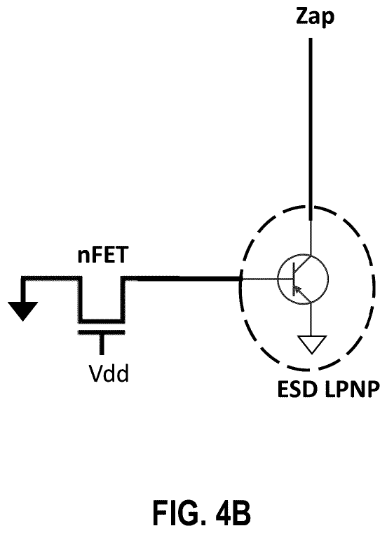

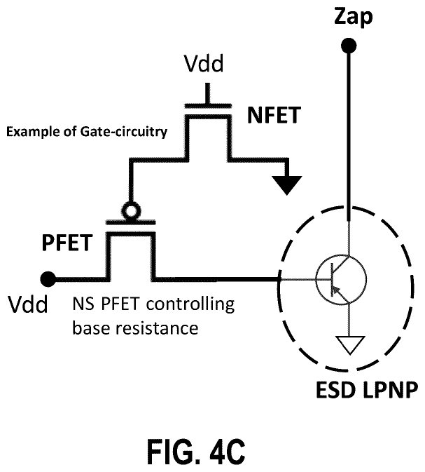

FIG. 4A illustrates an I-V diagram for an electrostatic discharge device, in accordance with an embodiment. The I-V correlation during the ESD event and during normal operation are shown. FIG. 4B illustrates an electrostatic discharge device circuitry associated with the semiconductor device shown in FIG. 3A. FIG. 4C illustrates an electrostatic discharge device circuitry associated with the semiconductor device shown in FIG. 3B.

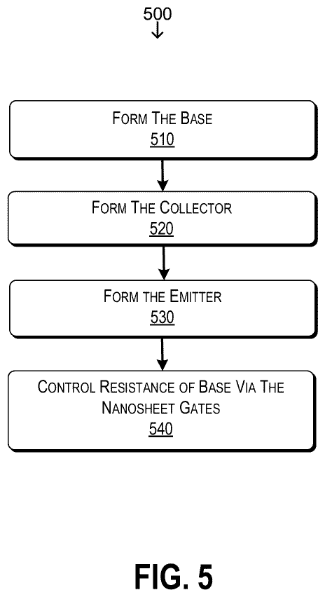

FIG. 5 illustrates a block diagram of a method 500 for forming the semiconductor device, in accordance with some embodiments. As shown by block 510, the base, including a first doped region, a second doped region, and a plurality of nanosheet gates are formed.

As shown by block 520, the collector including a third doped region is formed.

As shown by block 530, the emitter including a fourth doped region is formed.

As shown by block 540, a resistance of the base is controlled via the nanosheet gates.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a base comprising a first doped region, a second doped region and a plurality of nanosheet gates;
a collector comprising a third doped region; and
an emitter comprising a fourth doped region,
wherein the plurality of nanosheet gates is configured to control a resistance of the base.

2. The semiconductor device of claim 1, wherein the semiconductor device is a lateral N-type/P-type/N-type (LNPN) device, or a lateral P-type/N-type/P-type (LPNP) device.

3. The semiconductor device of claim 1, further comprising:
a first well region below the collector and the emitter; and
a second well region below the first well region and the base.

4. The semiconductor device of claim 1, wherein each of the base, the emitter, and the collector further comprises:
a spacer layer over sidewalls of a set of gate regions.

5. The semiconductor device of claim 1, wherein each of the base, the emitter, and the collector further comprises:
a frontside contact.

6. The semiconductor device of claim 1, wherein:
the plurality of nanosheet gates comprises alternative layers extended horizontally between a corresponding doped region and a gate region.

7. The semiconductor device of claim 6, wherein the alternative layers include silicon.

8. A method of fabricating a semiconductor device, the method comprising:
forming a base comprising a first doped region, a second doped region and a plurality of nanosheet gates;
forming a collector comprising a third doped region;
forming an emitter comprising a fourth doped region; and
controlling a resistance of the base via the plurality of nanosheet gates.

9. The method of claim 8, wherein the semiconductor device is a lateral N-type/P-type/N-type (LNPN) device, or a lateral P-type/N-type/P-type (LPNP) device.

10. The method of claim 8, further comprising:
forming a first well region below the collector and the emitter; and
forming a second well region below the first well region and the base.

11. The method of claim 8, wherein forming each of the base, the emitter, and the collector further comprises:
forming a spacer layer over sidewalls of a gate region.

12. The method of claim 8, wherein forming the plurality of nanosheet gates comprises:
extending the plurality of nanosheet gates horizontally between a corresponding doped region and a gate region.

13. The method of claim 8, wherein the plurality of nanosheet gates includes silicon.

14. A semiconductor device, comprising:
a base comprising a first doped region, a second doped region, a plurality of nanosheet gates;
a collector comprising a third doped region; and
an emitter comprising a fourth doped region,
wherein the plurality of nanosheet gates and an electrical connection between he base and the emitter are configured to control a resistance of the base.

15. The semiconductor device of claim 14, wherein the semiconductor device is a lateral N-type/P-type/N-type (LNPN) device, or a lateral P-type/N-type/P-type (LPNP) device.

16. The semiconductor device of claim 14, further comprising:
a first well region below the collector and the emitter; and
a second well region below the first well region and the base.

17. The semiconductor device of claim 14, wherein each of the base, the emitter, and the collector further comprises:
a spacer layer over sidewalls of a set of gate regions.

18. The semiconductor device of claim 14, wherein each of the base, the emitter, and the collector further comprises:
the plurality of nanosheet gates comprises alternative layers extended horizontally between a corresponding doped region and a gate region.

19. The semiconductor device of claim 18, wherein the alternative layers include silicon.

20. The semiconductor device of claim 14, wherein each of the base, the emitter, and the collector further comprises:
a frontside contact.
